(19) United States
(12) Patent Application Publication
(10) Pub. No.: US 2025/0224631 A1
(43) Pub. Date: Jul. 10, 2025

(54) SPATIAL LIGHT MODULATOR, ELECTRONIC APPARATUS INCLUDING THE SAME, AND METHOD OF FABRICATING SPATIAL LIGHT MODULATOR

(71) Applicant: SAMSUNG ELECTRONICS CO., LTD., Suwon-si (KR)

(72) Inventors: Sunil KIM, Suwon-si (KR); Junghyun PARK, Suwon-si (KR); Minkyung LEE, Suwon-si (KR); Byunggil JEONG, Suwon-si (KR)

(73) Assignee: SAMSUNG ELECTRONICS CO., LTD., Suwon-si (KR)

(21) Appl. No.: 18/775,602

(22) Filed: Jul. 17, 2024

(30) Foreign Application Priority Data
Jan. 9, 2024 (KR) 10-2024-0003627

(51) Int. Cl. G02F 1/015; G02F 1/01

(52) U.S. Cl. CPC G02F 1/015; G02F 1/0147; G02F 2201/346; G02F 2202/103; G02F 2203/50

(57) ABSTRACT

A spatial light modulator includes an upper reflective layer on which light is incident, a lower reflective layer below the upper reflective layer, and a cavity layer between the upper reflective layer and the lower reflective layer, the cavity layer having a refractive index configured to change based on an electrical signal, where the cavity layer includes a first material layer having a first refractive index, and at least one second material layer having a second refractive index that is less than the first refractive index.

### CROSS-REFERENCE TO RELATED APPLICATION

This application is based on and claims priority under 35 U.S.C. § 119 to Korean Patent Application No. 10-2024-0003627, filed on Jan. 9, 2024, in the Korean Intellectual Property Office, the disclosure of which is incorporated by reference herein in its entirety.

### BACKGROUND

### 1. Field

The disclosure relates to a spatial light modulator, an electronic apparatus including the same, and a method of fabricating the spatial light modulator.

### 2. Description of Related Art

In order to direct laser beams to desired locations, related art methods may include methods of mechanically rotating laser irradiation portions and methods of using optical phased array (OPA) methods. Recently, OPA methods, in which laser beams are directed by modulating the phases of laser beams incident on spatial light modulators and then the laser beams are emitted, have been spotlighted. Beam directing apparatuses using OPA methods may be applied to various fields, such as light detection and ranging (LiDAR) apparatuses and three-dimensional (3D) depth cameras that acquire distance information in each direction.

### SUMMARY

Provided are a spatial light modulator capable of reducing power consumption and an electronic apparatus including the same.

Provided are a spatial light modulator capable of increasing yield during fabrication and an electronic apparatus including the same.

Additional aspects will be set forth in part in the description which follows and, in part, will be apparent from the description, or may be learned by practice of the presented embodiments of the disclosure.

According to an aspect of the disclosure, a spatial light modulator may include an upper reflective layer on which light is incident, a lower reflective layer below the upper reflective layer, and a cavity layer between the upper reflective layer and the lower reflective layer, the cavity layer having a refractive index configured to change based on an electrical signal, where the cavity layer may include a first material layer having a first refractive index, and at least one second material layer having a second refractive index that is less than the first refractive index.

The at least one second material layer may include one second material layer, and the one second material layer may be on the first material layer.

The at least one second material layer may include two or more second material layers, and at least one of the two or more second material layers may be on the first material layer.

The first material layer may have a first thermo-optic coefficient that is greater than a second thermos-optic coefficient of the at least one second material layer.

The at least one second material layer may include an upper second material layer and a lower second material layer, the lower second material layer may be between the first material layer and the lower reflective layer, and the upper second material layer may be between the first material layer and the upper reflective layer.

The first material layer may include silicon (Si).

A thickness of the first material layer may be in a range of 370 nm to 470 nm.

The first material layer may have a P-I-N structure, a P-I-P structure, or an N-I-N structure.

The at least one second material layer may include silicon oxide (SiO₂).

A thickness of the at least one second material layer may be in a range of 40 nm to 350 nm.

The upper reflective layer may have a lower reflectance than the lower reflective layer.

The lower reflective layer may include a metal mirror layer or a distributed Bragg reflector.

The upper reflective layer may include a distributed Bragg reflector.

The upper reflective layer may include a high contrast grating (HCG) layer.

The light that is incident may have a wavelength of in a range of 900 nm to 1,000 nm.

According to an aspect of the disclosure, a method of fabricating a spatial light modulator may include forming a lower reflective layer, forming a first material layer on the lower reflective layer, measuring a thickness of the first material layer, determining, based on the measured thickness of the first material layer, a thickness of a second material layer such that a resonance wavelength of a cavity layer including the first material layer and the second material layer has a predetermined value, forming, on the first material layer, the second material layer having the determined thickness, and forming an upper reflective layer on the second material layer.

The first material layer may include silicon (Si), and the second material layer may include silicon oxide (SiO₂).

According to an aspect of the disclosure, an electronic apparatus may include a light source configured to emit light having a predetermined wavelength, and a spatial light modulator configured to modulate a phase of light incident from the light source and emit the incident light, where the spatial light modulator may include an upper reflective layer on which light is incident, a lower reflective layer below the upper reflective layer, and a cavity layer between the upper reflective layer and the lower reflective layer, and the cavity layer may include a first material layer having a first refractive index, and at least one second material layer having a second refractive index that is less than the first refractive index.

The predetermined wavelength may be in a range of 900 nm to 1,000 nm.

The at least one second material layer may include an upper second material layer and a lower second material layer, the lower second material layer may be between the first material layer and the lower reflective layer, and the upper second material layer may be between the first material layer and the upper reflective layer.

The upper reflective layer may include a first plurality of high refractive material layers and a first plurality of low refractive material layers alternately stacked.

The lower reflective layer may include a second plurality of high refractive material layers and a second plurality of low refractive material layers alternately stacked, the second plurality of high refractive material layers may be greater in number than the first plurality of high refractive material layers, and the second plurality of low refractive material layers may be greater in number than the first plurality of low refractive material layers.

The spatial light modulator may include an upper electrode and a lower electrode, and the first material layer may be between the upper electrode and the lower electrode.

The at least one second material layer may include an upper second material layer and a lower second material layer, the upper second material layer may be on the upper electrode, and the lower electrode may be on the lower second material layer.

The at least one second material layer may be on the upper electrode, and the spatial light modulator may include a plurality of grating elements periodically arranged on the at least one second material layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view illustrating a spatial light modulator according to one or more embodiments;

FIG. 2 is a cross-sectional view illustrating a pixel of a spatial light modulator according to one or more embodiments;

FIG. 3 is a graph illustrating an example of a change in a resonance wavelength of a cavity layer according to a change in a thickness of a first material layer within the cavity layer, according to one or more embodiments;

FIG. 4 is a graph illustrating an example of a change in a resonance wavelength of a cavity layer according to a change in a thickness of a second material layer within the cavity layer, according to one or more embodiments;

FIG. 5 is a graph illustrating a thickness of a second material layer for obtaining a resonance wavelength of 940 nm according to a measured thickness of a first material layer, according to one or more embodiments;

FIG. 6 is a cross-sectional view illustrating a pixel of a spatial light modulator according to one or more embodiments;

FIG. 7 is a cross-sectional view illustrating a pixel of a spatial light modulator according to one or more embodiments;

FIG. 8 is a cross-sectional view illustrating a pixel of a spatial light modulator according to one or more embodiments;

FIGS. 9A to 9D are diagrams illustrating a method of fabricating a spatial light modulator according to one or more embodiments; and

FIG. 10 is a diagram illustrating a beam directing system according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments will be described in detail with reference to the accompanying drawings. In the following drawings, the same reference numerals refer to the same components, and the size of each component in the drawings may be exaggerated for clarity and convenience of description. Embodiments described below are merely illustrative, and various modifications may be made from these embodiments.

In the following description, when a component is referred to as being “above” or “on” another component, it may be directly on an upper, lower, left, or right side of the other component while making contact with the other component or may be above an upper, lower, left, or right side of the other component without making contact with the other component.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural. Terms such as first, second, etc. may be used to describe various components, but are used only for the purpose of distinguishing one component from another component. These terms do not limit the difference in the material or structure of the components.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, terms such as “unit” and “module” described in the specification may indicate a unit that processes at least one function or operation, and this may be implemented as hardware or software, or may be implemented as a combination of hardware and software.

In addition, connections or connecting units of lines between components shown in the drawings are examples of functional connections and/or physical or circuit connections, and may be represented as alternative or additional various functional connections, physical connections, or circuit connections in real apparatuses.

In addition, the use of all examples or example terms is simply intended to describe the technical spirit in detail, and the scope of the disclosure is not limited by these examples or example terms unless they are limited by claims.

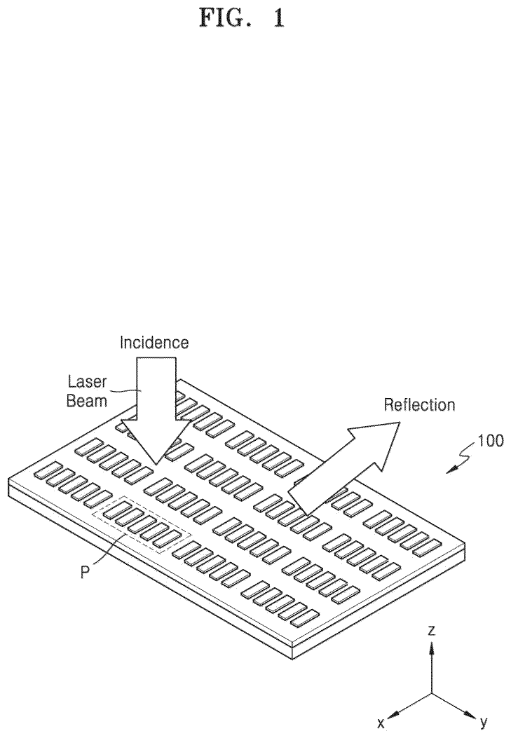

FIG. 1 is a perspective view illustrating a spatial light modulator 100 according to one or more embodiments. FIG. 1 illustrates the spatial light modulator 100 for modulating a phase of incident light and then emitting the modulated light. The spatial light modulator 100 may include a plurality of pixels P arranged in a predetermined form or pattern. The plurality of pixels P may be arranged in a one-dimensional or two-dimensional pattern. Each of the pixels P may have a refractive index that changes based on a voltage independently applied and thus may modulate a phase of incident light (e.g., a laser beam). Therefore, the pixels P of the spatial light modulator 100 may form a phase profile and enable beam directing for emitting light incident on the spatial light modulator 100 in a desired direction by controlling the phase profile. The light incident on the spatial light modulator 100 may have, for example, a wavelength of about 900 nm to about 1,000 nm. FIG. 1 illustrates that the spatial light modulator 100 is a reflective spatial light modulator, but the spatial light modulator 100 is not limited thereto and may be a transmissive spatial light modulator.

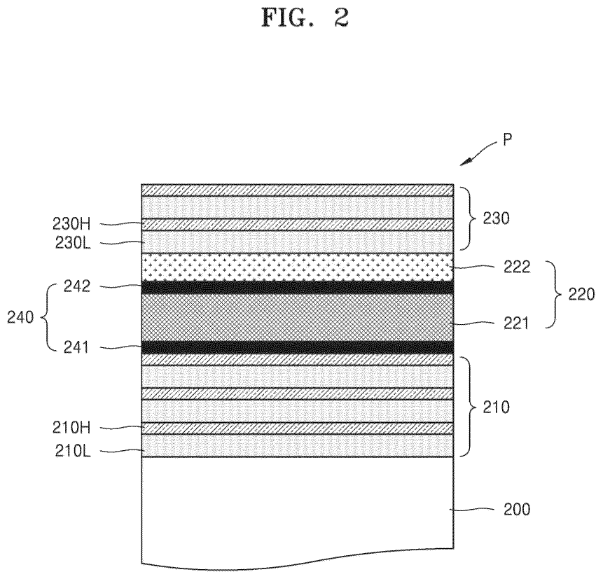

FIG. 2 is a cross-sectional view illustrating a pixel P of the spatial light modulator 100 according to one or more embodiments. Referring to FIG. 2, the spatial light modulator 100 may include an upper reflective layer 230 on which light is incident, a lower reflective layer 210 provided under the upper reflective layer 230, and a cavity layer 220 provided between the upper reflective layer 230 and the lower reflective layer 210, the cavity layer 220 having a refractive index that may change based on an applied electrical signal. The term “cavity layer” may refer to a layer formed by filling a cavity with one or more materials. For example, a layer created by filling a cavity with silicon (Si) may be referred to as a Si-filled cavity layer. The cavity layer 220 may include two or more material layers. For example, the cavity layer 220 may include a first material layer 221 and a second material layer 222. A refractive index (a first refractive index) of the first material layer 221 may be greater than a refractive index (a second refractive index) of the second material layer 222.

A substrate 200 may be a semiconductor substrate (for example, a silicon substrate) but is not limited thereto. A thickness of the substrate 200 may be determined by considering several factors, such as a form factor and/or heat emission when the spatial light modulator 100 is applied to a product. A circuit unit for driving and controlling the spatial light modulator 100 may be provided on the substrate 200.

The lower reflective layer 210 may be provided on the substrate 200. The lower reflective layer 210 may reflect light toward the upper reflective layer 230. A structure of the lower reflective layer 210 is not particularly limited. In the embodiment illustrated in FIG. 2, the lower reflective layer 210 may be a distributed Bragg reflector (DBR) in which at least one low refractive material layer 210L and at least one high refractive material layer 210H are alternately stacked. A material, thickness, and the like of each of the low refractive material layer 210L and the high refractive material layer 210H may be variously adjusted based on a reflectance design condition of the lower reflective layer 210. The high refractive material layer 210H may include a material having a higher refractive index than a refractive index of a material of the low refractive material layer 210L. The high refractive material layer 210H and the low refractive material layer 210L may include different materials from among Si, Si₃N₄, SiO₂, and TiO₂. For example, the low refractive material layer 210L may be a silicon oxide (SiO₂) layer, and the high refractive material layer 210H may be a silicon (Si) layer. The high refractive material layer 210H may have a smaller thickness than the low refractive material layer 210L. The thicknesses of the high refractive material layer 210H and the low refractive material layer 210L may be determined based on a wavelength of incident light, a refractive index of each layer, and reflectance of the lower reflective layer 210. As a non-limiting example, when the wavelength of the incident light is about 940 nm, the Si-high refractive material layer 210H may have a thickness of about 50 nm to about 90 nm, and the SiO₂-low refractive material layer 210L may have a thickness of about 140 nm to about 180 nm.

The upper reflective layer 230 may be spaced apart from the lower reflective layer 210 with the cavity layer 220 therebetween. In other words, the lower reflective layer 210 may be located underneath the cavity layer 220, and the upper reflective layer 230 may be located on the cavity layer 220. In one or more embodiments, the upper reflective layer 230 may be a DBR in which at least one low refractive material layer 230L and at least one high refractive material layer 230H are alternately stacked. A material, thickness, and the like of each of the low refractive material layer 230L and the high refractive material layer 230H may be variously adjusted based on a reflectance design condition of the upper reflective layer 230. The high refractive material layer 230H may include a material having a higher refractive index than a refractive index of the low refractive material layer 230L. The high refractive material layer 230H and the low refractive material layer 230L may include different materials from among Si, Si₃N₄, SiO₂, and TiO₂. For example, the low refractive material layer 230L may be a silicon oxide (SiO₂) layer, and the high refractive material layer 230H may be a silicon (Si) layer. The high refractive material layer 230H may have a smaller thickness than the low refractive material layer 230L. The thicknesses of the high refractive material layer 230H and the low refractive material layer 230L may be determined based on a wavelength of incident light, a refractive index of each layer, and reflectance of the upper reflective layer 230. As a non-limiting example, when the wavelength of the incident light is about 940 nm, the Si-high refractive material layer 230H may have a thickness of about 20 nm to about 90 nm, and the SiO₂-low refractive material layer 230L may have a thickness of about 20 nm to about 180 nm.

The reflectance of the upper reflective layer 230 may be lower than the reflectance of the lower reflective layer 210. Therefore, a phase of the incident light may be controlled up to 360°. To this end, the materials, thicknesses, and the like of the low refractive material layers 210L and 230L and the high refractive material layers 210H and 230H forming the lower reflective layer 210 and the upper reflective layer 230 may be determined to satisfy a condition that the reflectance of the upper reflective layer 230 is lower than the reflectance of the lower reflective layer 210. For example, the number of stacks of pairs of the low refractive material layer 210L and the high refractive material layer 210H of the lower reflective layer 210 may be greater than the number of stacks of pairs of the low refractive material layer 230L and the high refractive material layer 230H of the upper reflective layer 230. For example, the number of stacks of the lower reflective layer 210 may be three or more, and the number of stacks of the upper reflective layer 230 may be two or less. FIG. 2 illustrates that the number of stacks of the lower reflective layer 210 is three and the number of stacks of the upper reflective layer 230 is two. However, the number of stacks of the lower reflective layer 210 and the number of stacks of the upper reflective layer 230 are not limited thereto and may be variously modified so that the reflectance of the upper reflective layer 230 is lower than the reflectance of the lower reflective layer 210.

The cavity layer 220 may be provided between the lower reflective layer 210 and the upper reflective layer 230. The cavity layer 220 may resonate and amplify incident light between the lower reflective layer 210 and the upper reflective layer 230. The cavity layer 220 may include a plurality of material layers. At least one of the plurality of material layers may have a different refractive index from the remaining material layers. For example, the cavity layer 220 may include a first material layer 221 and a second material layer 222. A refractive index (a first refractive index) of the first material layer 221 may be greater than a refractive index (a second refractive index) of the second material layer 222. A thermo-optic coefficient of the first material layer 221 may be greater than a thermo-optic coefficient of the second material layer 222. A thermo-optic coefficient may refer to a change in a refractive index that occurs based on a change in a temperature of a material. For example, the second material layer 222 may be stacked on the first material layer 221. In other words, the second material layer 222 may be an uppermost layer of the cavity layer 220.

For example, the first material layer 221 may include silicon (Si). The first material layer 221 may have a P-I-N structure, a P-I-P structure, or an N-I-N structure. P may refer to a p-type semiconductor, I may refer to an intrinsic semiconductor, and N may refer to an n-type semiconductor. For example, when the first material layer 221 includes silicon (Si), the P-I-N structure may be a p-type Si (p-Si)/intrinsic Si (i-Si)/n-type Si (n-Si) structure. The second material layer 222 may include a material having a lower refractive index and a lower thermo-optic coefficient than the first material layer 221. For example, the second material layer 222 may include SiO₂ or Si₃N₄. A thickness of the first material layer 221 may be, for example, about 370 nm about to 470 nm, and a thickness of the second material layer 222 may be about 40 nm to about 350 nm to modulate incident light in a wavelength range of about 900 nm to about 1,000 nm.

An electrical signal may be applied to the cavity layer 220 (for example, to the first material layer 221) through an electrode 240. The electrode 240 may include a first electrode 241 and a second electrode 242. The first electrode 241 and the second electrode 242 may be electrically connected to a lower surface and an upper surface of the first material layer 221, respectively. The first electrode 241 and the second electrode 242 may directly contact the lower surface and the upper surface of the first material layer 221, respectively. For example, the first electrode 241 may be a common electrode, and the second electrode 242 may be a driving electrode. The first electrode 241 and the second electrode 242 may include, for example, a doped semiconductor material. In one or more embodiments, when the cavity layer 220 includes Si, the first electrode 241 and the second electrode 242 may include n-doped Si. However, the first electrode 241 and the second electrode 242 are not limited thereto. For example, the first electrode 241 and the second electrode 242 may include transparent conductive oxide (TCO) having transmittance with respect to light in an operating wavelength range of the spatial light modulator 100. The TCO may include, for example, ITO, IWO, IZO, GZO, GIZO, or AZO.

Due to the above structure, when a current is applied to the first material layer 221 through the first electrode 241 and the second electrode 242, Joule heat may be generated, and a refractive index of a material (e.g., Si) constituting the cavity layer 220 (for example, the first material layer 221) may change. Accordingly, the plurality of pixels P may form a phase profile and enable beam directing for emitting light incident on the spatial light modulator 100 in a desired direction by controlling the phase profile.

The refractive index of the cavity layer 220 may affect power consumption of the spatial light modulator 100. When the refractive index of the cavity layer 220 is constant, a thickness of the cavity layer 220 may affect a resonance wavelength of the cavity layer 220. The thickness of the cavity layer 220 may be determined based on an operating wavelength of the spatial light modulator 100. Dispersion may occur in the thickness of the cavity layer 220 in a process of fabricating the cavity layer 220. When the thickness of the cavity layer 220 changes, the resonance wavelength may change. For example, when the cavity layer 220 has a high refractive index material (e.g., a silicon (Si) single layer structure), the refractive index thereof may greatly change based on an applied voltage, and thus, power consumption may be low when the spatial light modulator 100 is driven. However, the cavity layer 220 having a desired resonance wavelength may not be easily formed in the fabrication process due to a large amount of dispersion in the resonance wavelength corresponding to a thickness dispersion of a silicon Si layer forming the cavity layer 220. When the cavity layer 220 has a low refractive index material (for example, a silicon oxide (SiO₂) single layer structure), securing the cavity layer 220 having the desired resonance wavelength may be easy in the fabrication process due to small dispersion of the resonance wavelength corresponding to the thickness dispersion of a silicon oxide (SiO₂) layer forming the cavity layer 220, but due to a small change in the refractive index based on the applied voltage, power consumption may increase when the spatial light modulator 100 is driven.

In one or more embodiments, the cavity layer 220 having a multilayer structure in which the first material layer 221 having a relatively high refractive index and the second material layer 222 having a relatively low refractive index are stacked may be used. An effective refractive index of the cavity layer 220 may be determined by considering a volume fraction of the first material layer 221 and the second material layer 222. The second material layer 222 may have a relatively low refractive index, and thus, thickness dispersion of the second material layer 222 may have less influence on the resonance wavelength of the cavity layer 220. Therefore, the cavity layer 220 having a multilayer structure in which a low refractive index material layer and a high refractive index material layer are stacked may have a smaller change in the resonance wavelength thereof due to smaller thickness dispersion than that of a single layer structure-cavity layer having a high refractive index material layer, and thus, the cavity layer 220 having a desired resonance wavelength may be easily implemented.

The second material layer 222 may be located on the first material layer 221. In other words, the second material layer 222 may be an uppermost material layer of the cavity layer 220. Even when dispersion occurs in the thickness of the first material layer 221 during the fabrication process, the second material layer 222 having the thickness capable of compensating for the dispersion may be formed on the first material layer 221, and thus, as a whole, the cavity layer 220 may have a thickness capable of easily securing a desired resonance wavelength. In other words, during the fabrication process, after the first material layer 221 is formed, the thickness of the first material layer 221 may be measured to determine the thickness dispersion of the first material layer 221. Subsequently, the second material layer 222 may be formed on the first material layer 221 to have a thickness capable of compensating for the thickness dispersion of the first material layer 221. Accordingly, even when the thickness dispersion of the first material layer 221 occurs, the cavity layer 220 having the desired resonance wavelength may be easily formed. In addition, the first material layer 221 having a relatively high refractive index may function as a refractive index change layer having a refractive index changing based on an electrical signal, and thus, the spatial light modulator 100 having low power consumption may be implemented.

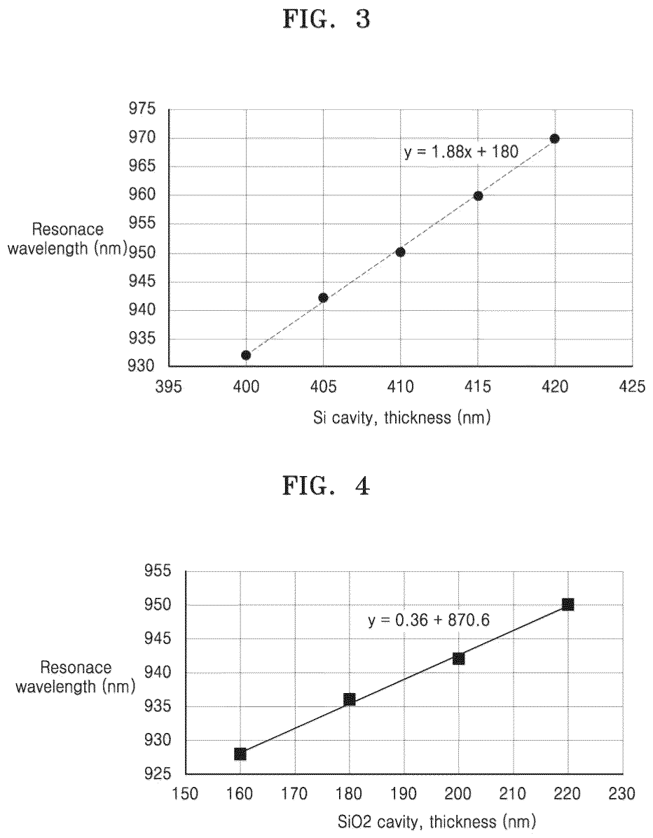

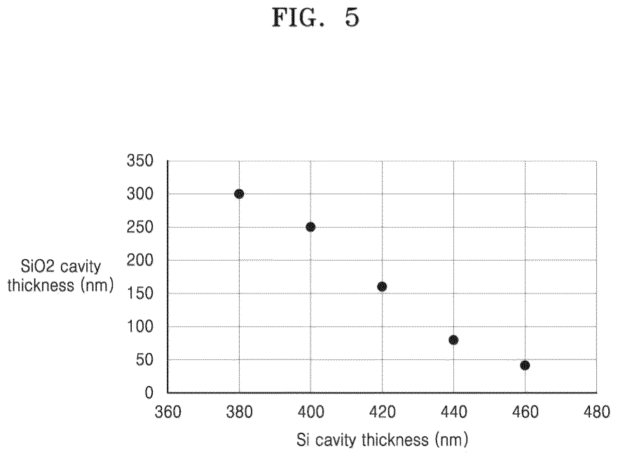

FIG. 3 is a graph illustrating an example of a change in a resonance wavelength of the cavity layer 220 according to a change in a thickness of the first material layer 221 within the cavity layer 220, according to one or more embodiments. FIG. 4 is a graph illustrating an example of a change in a resonance wavelength of the cavity layer 220 according to a change in a thickness of the second material layer 222 within the cavity layer 220, according to one or more embodiments. FIG. 5 is a graph illustrating a thickness of the second material layer 222 for obtaining a resonance wavelength of 940 nm according to a measured thickness of the first material layer 221, according to one or more embodiments. The graphs of FIGS. 3, 4, and 5 are examples, and the scope of the disclosure is not limited by detailed numerical values shown in FIGS. 3, 4, and 5.

As illustrated in FIG. 3, the first material layer 221 may be a silicon (Si) layer, and the second material layer 222 may be a silicon oxide (SiO₂) layer. The thickness of the second material layer 222 may have a fixed value. Referring to FIG. 3, when a thickness of the silicon (Si) layer changes by 10 nm, a resonance wavelength of the cavity layer 220 may change by about 18.8 nm. Thickness dispersion in a deposition process of a general silicon (Si) layer may be about 5% to about 10%. The thickness of the silicon (Si) layer for obtaining the resonance wavelength of about 940 nm may be about 404 nm. When the deposition process is performed by setting a target thickness of the silicon (Si) layer to about 404 nm and the thickness dispersion is 5%, an actual thickness of the silicon (Si) layer may be about 404±20 nm. The resonance wavelength of the cavity layer 220 may be about 940±36 nm. A wavelength range of light incident on the spatial light modulator 100 (e.g., laser light) may be about 940±5 nm, and thus, the high-quality spatial light modulator 100 may not be easily obtained due to the thickness dispersion in the deposition process when the resonance wavelength of the cavity layer 220 needs to be secured only by the thickness of the silicon (Si) layer.

As illustrated in FIG. 4, the first material layer 221 may be a silicon (Si) layer, and the second material layer 222 may be a silicon oxide (SiO₂) layer. A thickness of the first material layer 221 may have a fixed value. Referring to FIG. 4, when a thickness of the silicon oxide (SiO₂) layer changes by 10 nm, a resonance wavelength of the cavity layer 220 may change by about 3.6 nm. An amount of change in the resonance wavelength of the cavity layer 220 according to a change in the thickness of the silicon oxide (SiO₂) layer may be about ⅕ of the amount of change in the resonance wavelength of the cavity layer 220 according to the change in the thickness of the silicon (Si) layer. Therefore, compared to the case where the resonance wavelength of the cavity layer 220 needs to be secured only by the thickness of the silicon (Si) layer, a defect rate due to the thickness dispersion in the deposition process may be lowered, and the high-quality spatial light modulator 100 may be easily obtained.

As described above, after forming the first material layer 221 and measuring the thickness of the first material layer 221, the thickness of the second material layer 222 for obtaining the desired resonance wavelength may be determined. The second material layer 222 may be formed based on the determined thickness. For example, FIG. 5 illustrates the thickness of the silicon oxide (SiO₂) layer for obtaining the resonance wavelength of 940 nm based on the thickness of the silicon (Si) layer after the silicon (Si) layer is formed. According to one or more embodiments as illustrated in FIG. 5, a resonance wavelength of 940 nm±5 nm may be obtained.

As described above, with the cavity layer 220 having the multilayer structure according to one or more embodiments, when using the first material layer 221 having a high refractive index and thermo-optic coefficient as a refractive index change layer, a change in refractive index may be high compared to an applied voltage, and thus, power consumption may be lowered. In addition, compared to a cavity layer having a single layer structure, high yield may be implemented by lowering a defect rate due to a process dispersion of the thickness.

A cavity layer may include a single second material layer, but the cavity layer may include two or more second material layers. At least one of the two or more second material layers may be located on a first material layer.

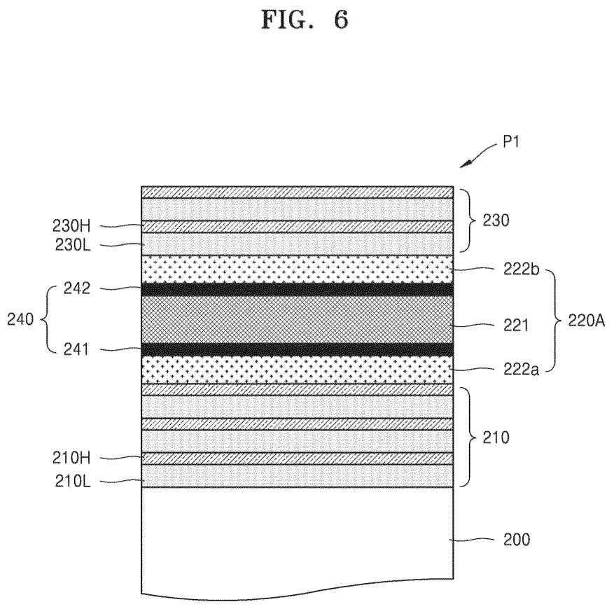

FIG. 6 is a cross-sectional view illustrating a pixel P1 of the spatial light modulator 100 according to one or more embodiments. The pixel P1 is different from the pixel P of the embodiment shown in FIG. 2 in that a cavity layer 220A having a three-layer structure is used. Hereinafter, components of FIG. 6 having the same functions as the components of FIG. 2 are indicated by the same reference numerals, and the same descriptions thereof may be omitted.

Referring to FIG. 6, the cavity layer 220A may include two second material layers 222a and 222b. The second material layer 222a may be located underneath a first material layer 221 (i.e., between a lower reflective layer 210 and the first material layer 221). The second material layer 222b may be located on the first material layer 221 (i.e., between the first material layer 221 and an upper reflective layer 230). A refractive index of each of the second material layers 222a and 222b may be less than a refractive index of the first material layer 221. The second material layers 222a and 222b may be the same material layer or different material layers. In one or more embodiments, the first material layer 221 may include silicon (Si), and the second material layers 222a and 222b may include silicon oxide (SiO₂).

A resonance wavelength of the cavity layer 220A may be affected by the refractive index and thickness of each of the first material layer 221 and the second material layers 222a and 222b. The second material layer 222a having a predetermined thickness may be formed, and the first material layer 221 may be formed thereon. Subsequently, the thickness of the first material layer 221 may be measured, and the second material layer 222b having an appropriate thickness may be formed on the first material layer 221 such that the resonance wavelength of the cavity layer 220A has a desired resonance wavelength. For example, to obtain a resonance wavelength of 940 nm, the thickness of the second material layer 222b may be determined and the second material layer 222b having the corresponding thickness may be formed, such that the sum of the thicknesses of the second material layer 222a and the second material layer 222b corresponds a thickness of the silicon oxide (SiO₂) layer corresponding to the thickness of the silicon (Si) layer measured on the graph shown in FIG. 5.

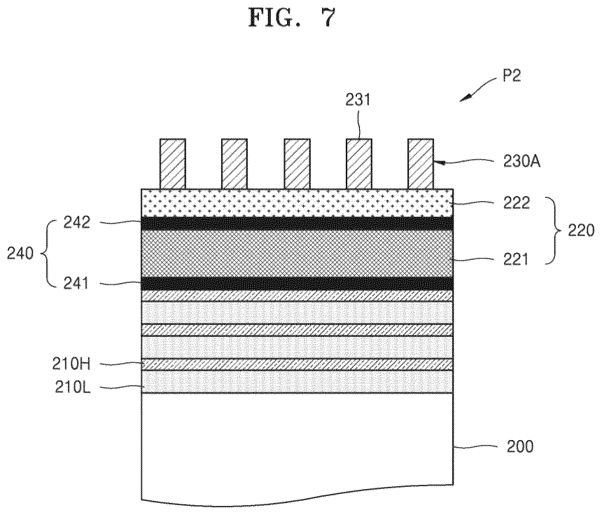

FIG. 7 is a cross-sectional view illustrating a pixel P2 of the spatial light modulator 100 according to one or more embodiments. The pixel P2 is different from the pixel P of the embodiment shown in FIG. 2 in that a high contrast grating (HCG) layer 230A constituting an active meta surface is used as an upper reflective layer. The upper reflective layer 230 having a DBR structure in the pixel P1 shown in FIG. 6 may be replaced with the HCG layer 230A. Hereinafter, components of FIG. 7 having the same functions as the components of FIG. 2 are indicated by the same reference numerals, and the same descriptions thereof may be omitted.

Referring to FIG. 7, the HCG layer 230A that functions as the upper reflective layer may be provided on the cavity layer 220. The HCG layer 230A may form the active meta surface on the cavity layer 220. The HCG layer 230A may have a structure in which a plurality of grating elements 231 are periodically arranged on an upper surface of the cavity layer 220. Shapes and dimensions of the plurality of grating elements 231 may be substantially the same as one another. At least one of a height (a thickness), a width, and a period of each of the grating elements 231 may be smaller than a wavelength of incident light. Desired reflectance may be obtained in a desired wavelength band by controlling the height (thickness) and width of each of the grating elements 231, and/or pitch of the grating elements 231. For example, the height and width of each of the grating elements 231, and/or pitch of the grating elements 231 may be designed such that the reflectance of the HCG layer 230A may be about 70% or more. The plurality of grating elements 231 may be one-dimensionally arranged. The arrangement period of the plurality of grating elements 231 may be smaller than the wavelength of the incident light. In this regard, the HCG layer 230A may be referred to as an active meta surface or an active meta surface layer, and each of the grating elements 231 may be referred to as an active meta pattern or an active meta diffraction pattern. Each of the grating elements 231 may include a high refractive material, for example, silicon. Each of the grating elements 231 may be formed of amorphous silicon or crystalline silicon (e.g., polycrystalline silicon), but is not limited thereto. In an example, each of the grating elements 231 may be formed of polycrystalline silicon having a relatively small grain size.

A protective layer may be provided between the cavity layer 220 and the HCG layer 230A. The protective layer may prevent peeling off from occurring during an annealing process of a cavity layer material (e.g., Si, SiO₂, or the like) for generating Joule heat. The protective layer may include, for example, at least one of silicon oxide, silicon nitride, aluminum oxide, hafnium oxide, and titanium oxide. However, the protective layer is not limited thereto and may have a thickness of about 20 nm to about 200 nm, but is only example.

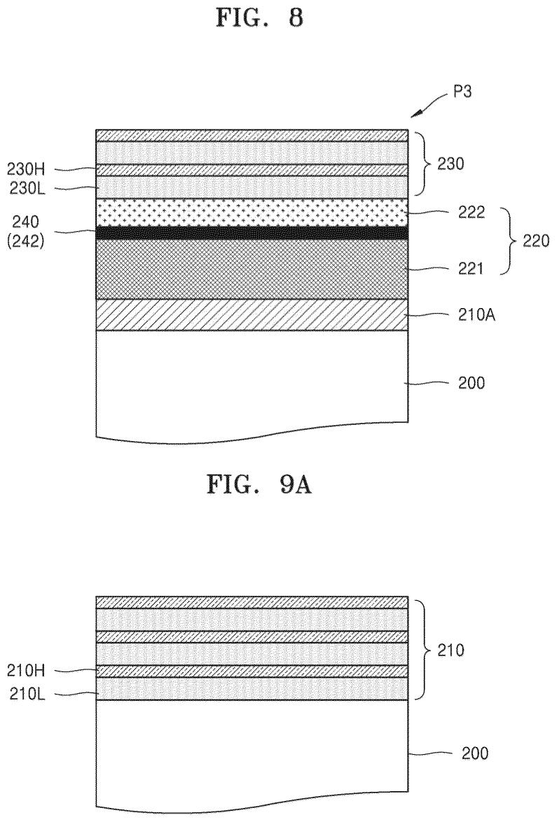

FIG. 8 is a cross-sectional view illustrating a pixel P3 of the spatial light modulator 100 according to one or more embodiments. The pixel P3 is different from the pixel P of the embodiment shown in FIG. 2 in that a metal mirror layer 210A is used as a lower reflective layer. The lower reflective layer 210 having a DBR structure in the pixels P1 and P2 shown in FIGS. 6 and 7, respectively, may be replaced with the metal mirror layer 210A. Hereinafter, components of FIG. 8 having the same functions as the components of FIG. 2 are indicated by the same reference numerals, and the same descriptions thereof may be omitted.

Referring to FIG. 8, the metal mirror layer 210A may be provided on a substrate 200. A cavity layer 220 and an upper reflective layer 230 may be sequentially provided on the metal mirror layer 210A. The metal mirror layer 210A may be formed of metal having high reflectance (for example, Cu, Al, Ni, Pd, Pt, Ag, Au, or an alloy including at least one thereof). When the metal mirror layer 210A is a conductive layer, the metal mirror layer 210A may function as an electrode for supplying a current to a first material layer 221. The electrode 241 shown in FIG. 2 may be omitted herein. The metal mirror layer 210A may function as a common electrode, and the electrode 242 may function as a driving electrode.

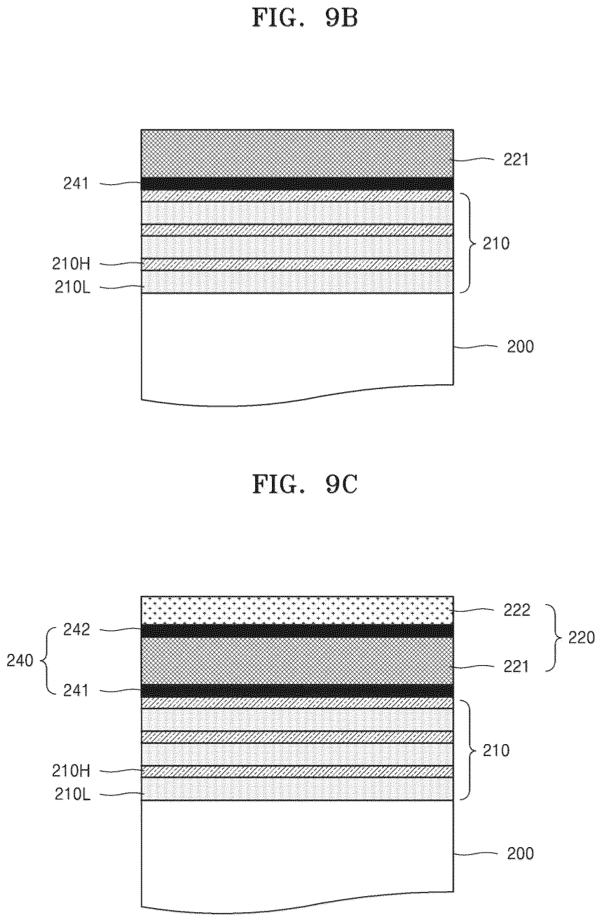

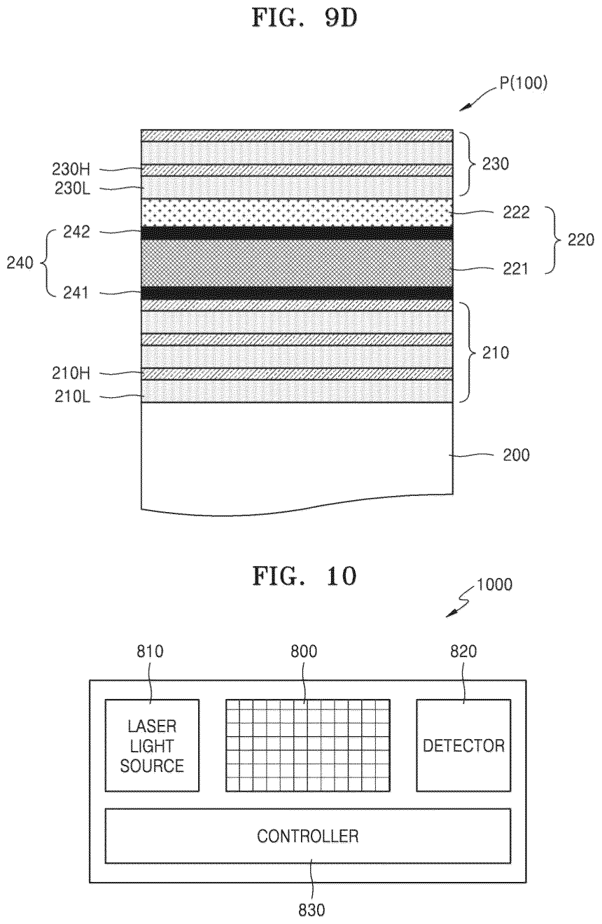

FIGS. 9A to 9D are diagrams illustrating a method of fabricating a spatial light modulator 100 according to one or more embodiments. Referring to FIGS. 9A to 9D, the method of fabricating the spatial light modulator 100 according to one or more embodiments may include an operation of forming a lower reflective layer 210, an operation of forming a first material layer 221 on the lower reflective layer 210, an operation of measuring a thickness of the first material layer 221, an operation of determining, based on the measured thickness of the first material layer 221, a thickness of a second material layer 222 in which a resonance wavelength of a cavity layer 220 including the first material layer 221 and the second material layer 222 has a predetermined value, an operation of forming the second material layer 222 on the first material layer 221 to have the determined thickness, and an operation of forming an upper reflective layer 230 on the second material layer 222.

Referring to FIG. 9A, a substrate 200 may be provided. The substrate 200 may be a semiconductor substrate (for example, a silicon substrate or a glass substrate). The lower reflective layer 210 may be formed on the substrate 200. In one or more embodiments, the lower reflective layer 210 may include a DBR. The lower reflective layer 210 may be formed by alternately stacking a low refractive material layer 210L and a high refractive material layer 210H. The high refractive material layer 210H and the low refractive material layer 210L may include different materials from among Si, Si₃N₄, SiO₂, and TiO₂. For example, the low refractive material layer 210L may be a silicon oxide (SiO₂) layer, and the high refractive material layer 210H may be a silicon (Si) layer. A material, thickness, and the like of each of the high refractive material layer 210H and the low refractive material layer 210L may be determined based on a wavelength of incident light, a refractive index of each layer, and reflectance of the lower reflective layer 210. As a non-limiting example, when the wavelength of the incident light is about 940 nm, the Si-high refractive material layer 210H may have a thickness of about 60 nm to about 90 nm, and the SiO₂-low refractive material layer 210L may have a thickness of about 140 nm to about 170 nm. The number of stacks of pairs of the low refractive material layer 210L and the high refractive material layer 210H may be, for example, three or more.

As shown in FIG. 9B, the first material layer 221 may be formed on the lower reflective layer 210 to have a first target thickness. In one or more embodiments, an electrode 241 may be formed on the lower reflective layer 210, and then the first material layer 221 may be formed thereon. The electrode 241 may be formed of TCO having transmittance with respect to light in an operating wavelength range of the spatial light modulator 100 (for example, ITO, IWO, IZO, GZO, GIZO, or AZO). The first material layer 221 may be formed of a high refractive index material, such as silicon (Si). The first material layer 221 may have a P-I-N structure, a P-I-P structure, or an N-I-N structure.

The operation of determining the thickness of the second material layer 222 may be performed. The thickness of the first material layer 221 may be measured. The thickness of the first material layer 221 may be measured using various methods. As an example, after forming the first material layer 221, the first material layer 221 may be partially etched to form a step, and the thickness of the first material layer 221 may be measured by measuring the step by using a thin film thickness measurement device, for example, an alpha-step measurement device. Subsequently, the thickness of the second material layer 222 may be determined based on the measured thickness of the first material layer 221, such that the resonance wavelength of the cavity layer 220 including the first material layer 221 and the second material layer 222 has a predetermined value. The resonance wavelength of the cavity layer 220 may correspond to an operating wavelength of the spatial light modulator 100. For example, the resonance wavelength of the cavity layer 220 may be about 900 nm to about 1,000 nm. For example, when the first material layer 221 is formed of silicon (Si), the second material layer 222 may be determined to be formed of silicon oxide (SiO₂). The operating wavelength of the spatial light modulator 100 may be about 940 nm, and the thickness of the second material layer 222 corresponding to the thickness of the first material layer 221 measured as in FIG. 5 may be determined.

As shown in FIG. 9C, the second material layer 222 may be formed by depositing, for example, silicon oxide (SiO₂), on the first material layer 221 to have the determined thickness. Before forming the second material layer 222, an electrode 242 may be formed on the first material layer 221, and the second material layer 222 may be formed by depositing, for example, silicon oxide (SiO₂), thereon to have the determined thickness.

As shown in FIG. 9D, the upper reflective layer 230 may be formed on the second material layer 222. In one or more embodiments, the upper reflective layer 230 may include a DBR. The upper reflective layer 230 may be formed by alternately stacking a low refractive material layer 230L and a high refractive material layer 230H. The high refractive material layer 230H and the low refractive material layer 230L may include different materials from among Si, Si₃N₄, SiO₂, and TiO₂. For example, the low refractive material layer 230L may be a silicon oxide (SiO₂) layer, and the high refractive material layer 230H may be a silicon (Si) layer. A material, thickness, and the like of each of the high refractive material layer 230H and the low refractive material layer 230L may be determined based on a wavelength of incident light, a refractive index of each layer, and reflectance of the upper reflective layer 230. As a non-limiting example, when the wavelength of the incident light is about 940 nm, the Si-high refractive material layer 230H may have a thickness of about 60 nm to about 90 nm, and the SiO₂-low refractive material layer 230L may have a thickness of about 140 nm to about 170 nm. Reflectance of the upper reflective layer 230 may be lower than reflectance of the lower reflective layer 210. Accordingly, for example, the number of stacks of the upper reflective layer 230 may be less than the number of stacks of the lower reflective layer 210. For example, the number of stacks of the upper reflective layer 230 may be two or less.

In one or more embodiments, based on the above-described fabricating method, fabrication yield of the spatial light modulator 100 may be improved by lowering a defect rate according to a process dispersion of the thickness of the cavity layer 220 compared to a cavity layer having a single layer structure. In addition, when using the first material layer 221 having a high refractive index and thermo-optic coefficient as a refractive index change layer, a refractive index may greatly change compared to an applied voltage, and thus, the spatial light modulator 100 having low power consumption may be fabricated.

The spatial light modulator 100 according to one or more embodiments described above may be applied to a beam directing system for directing an incident laser beam in a desired direction.

FIG. 10 is a diagram illustrating a beam directing system according to one or more embodiments. Referring to FIG. 10, the beam directing system 1000 may include a laser light source 810 for emitting a laser beam of a predetermined wavelength, a spatial light modulator 800 for directing an incident laser beam, a detector 820 for detecting the directed laser beam, and a controller 830. Here, the controller 830 may include a driving circuit for driving the laser light source 810, the spatial light modulator 800, and the detector 820.

The laser light source 810 may emit a laser beam having a wavelength of about 900 nm to about 1,000 nm. A laser diode may be used as the laser light source 810, but is only an example. The laser beam emitted from the laser light source 810 may be incident on the spatial light modulator 800. The spatial light modulator 800 may direct the laser beam in a desired direction by modulating a phase of the incident laser beam and then emitting the laser beam. The spatial light modulator 800 may be any one of the spatial light modulators 100 according to one or more embodiments. When the laser beam directed by the spatial light modulator 800 is irradiated to and reflected from an object, the detector 820 may detect the reflected laser beam.

The beam directing system 1000 described above may be applied to various types of electronic apparatuses such as a three-dimensional (3D) depth camera, a depth sensor, a 3D sensor, and light detection and ranging (LiDAR) that acquire distance information for each direction.

According to one or more embodiments, with a spatial light modulator described above, by using a cavity layer including a first material layer having a high refractive index and a second material layer having a relatively low refractive index, yield of the spatial light modulator may be improved by reducing the occurrence of defects due to a thickness dispersion of the cavity layer in a fabrication process of the cavity layer.

In addition, power consumption of the spatial light modulator may be reduced by using the first material layer having the high refractive index as a refractive index change layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A spatial light modulator comprising:
an upper reflective layer on which light is incident;
a lower reflective layer below the upper reflective layer; and
a cavity layer between the upper reflective layer and the lower reflective layer, the cavity layer having a refractive index configured to change based on an electrical signal,
wherein the cavity layer comprises:
a first material layer having a first refractive index; and
at least one second material layer having a second refractive index that is less than the first refractive index.

2. The spatial light modulator of claim 1, wherein the at least one second material layer consists of one second material layer, and
wherein the one second material layer is on the first material layer.

3. The spatial light modulator of claim 1, wherein the at least one second material layer comprises two or more second material layers, and
wherein at least one of the two or more second material layers is on the first material layer.

4. The spatial light modulator of claim 1, wherein the first material layer has a first thermo-optic coefficient that is greater than a second thermos-optic coefficient of the at least one second material layer.

5. The spatial light modulator of claim 1, wherein the at least one second material layer comprises an upper second material layer and a lower second material layer,
wherein the lower second material layer is between the first material layer and the lower reflective layer, and
wherein the upper second material layer is between the first material layer and the upper reflective layer.

6. The spatial light modulator of claim 1, wherein the first material layer comprises silicon (Si).

7. The spatial light modulator of claim 6, wherein a thickness of the first material layer is in a range of 370 nm to 470 nm.

8. The spatial light modulator of claim 6, wherein the first material layer has a P-I-N structure, a P-I-P structure, or an N-I-N structure.

9. The spatial light modulator of claim 6, wherein the at least one second material layer comprises silicon oxide (SiO₂).

10. The spatial light modulator of claim 6, wherein a thickness of the at least one second material layer is in a range of 40 nm to 350 nm.

11. The spatial light modulator of claim 1, wherein the upper reflective layer has a lower reflectance than the lower reflective layer.

12. The spatial light modulator of claim 1, wherein the lower reflective layer comprises a metal mirror layer or a distributed Bragg reflector.

13. The spatial light modulator of claim 1, wherein the upper reflective layer comprises a distributed Bragg reflector.

14. The spatial light modulator of claim 1, wherein the upper reflective layer comprises a high contrast grating (HCG) layer.

15. The spatial light modulator of claim 1, wherein the light that is incident has a wavelength of in a range of 900 nm to 1,000 nm.

16. A method of fabricating a spatial light modulator, the method comprising:
forming a lower reflective layer;
forming a first material layer on the lower reflective layer;
measuring a thickness of the first material layer;
determining, based on the measured thickness of the first material layer, a thickness of a second material layer such that a resonance wavelength of a cavity layer comprising the first material layer and the second material layer has a predetermined value;
forming, on the first material layer, the second material layer having the determined thickness; and
forming an upper reflective layer on the second material layer.

17. The method of claim 16, wherein the first material layer comprises silicon (Si), and
wherein the second material layer comprises silicon oxide (SiO₂).

18. An electronic apparatus comprising:
a light source configured to emit light having a predetermined wavelength; and
a spatial light modulator configured to modulate a phase of light incident from the light source and emit the incident light,
wherein the spatial light modulator comprises:
an upper reflective layer on which light is incident;
a lower reflective layer below the upper reflective layer; and
a cavity layer between the upper reflective layer and the lower reflective layer, and
wherein the cavity layer comprises:
a first material layer having a first refractive index; and
at least one second material layer having a second refractive index that is less than the first refractive index.

19. The electronic apparatus of claim 18, wherein the predetermined wavelength is in a range of 900 nm to 1,000 nm.

20. The electronic apparatus of claim 18, wherein the at least one second material layer comprises an upper second material layer and a lower second material layer,
wherein the lower second material layer is between the first material layer and the lower reflective layer, and
wherein the upper second material layer is between the first material layer and the upper reflective layer.

21. The electronic apparatus of claim 18, wherein the upper reflective layer comprises a first plurality of high refractive material layers and a first plurality of low refractive material layers alternately stacked.

22. The electronic apparatus of claim 21, wherein the lower reflective layer comprises a second plurality of high refractive material layers and a second plurality of low refractive material layers alternately stacked,
wherein the second plurality of high refractive material layers is greater in number than the first plurality of high refractive material layers, and
wherein the second plurality of low refractive material layers is greater in number than the first plurality of low refractive material layers.

23. The electronic apparatus of claim 18, wherein the spatial light modulator further comprises an upper electrode and a lower electrode, and
wherein the first material layer is between the upper electrode and the lower electrode.

24. The electronic apparatus of claim 23, wherein the at least one second material layer comprises an upper second material layer and a lower second material layer,
wherein the upper second material layer is on the upper electrode, and
wherein the lower electrode is on the lower second material layer.

25. The electronic apparatus of claim 23, wherein the at least one second material layer is on the upper electrode, and
wherein the spatial light modulator further comprises a plurality of grating elements periodically arranged on the at least one second material layer.
